(19) United States
(12) Patent Application Publication
(10) Pub. No.: US 2009/0057662 A1
(43) Pub. Date: Mar. 5, 2009

(54) Nanoparticle Semiconductor Device and Method for Fabricating

(75) Inventors: Paul W. Brazis, South Elgin, IL (US); Daniel R. Gamota, Palatine, IL (US); Dale R. McClure, Romeoville, IL (US); Andrew F. Skipor, West Chicago, IL (US); Jie Zhang, Buffalo Grove, IL (US)

Correspondence Address: LEVEQUE INTELLECTUAL PROPERTY LAW, P.C., 221 EAST CHURCH ST., FREDERICK, MD, 21701, US

(73) Assignee: MOTOROLA, INC., Schaumburg, IL (US)

(21) Appl. No.: 11/846,805

(22) Filed: Aug. 29, 2007

(51) Int. Cl. H01L 29/12; H01L 21/20

(52) U.S. Cl. 257/43; 438/104; 438/479; 257/E29.068; 257/E21.09

(57) ABSTRACT

A low-temperature process for creating a semiconductive device by printing a liquid composition containing semiconducting nanoparticles. The semiconductive device is formed on a polymeric substrate by printing a composition that contains nanoparticles of inorganic semiconductor suspended in a carrier, using a graphic arts printing method. The printed deposit is then heated to remove substantially all of the carrier from the printed deposit. The low-temperature process does not heat the substrate or the printed deposit above 300° C. The mobility of the resulting semiconductive device is between about 10 cm²/Vs and 200 cm²/Vs.

### FIELD OF THE INVENTION

The present invention relates generally to semiconductor devices, and more particularly, to devices where the semiconductive portion is made from nanoparticles and printed using a process that does not involve intense heating.

### BACKGROUND

Conductive traces for electronic circuits and passive devices such as resistors and capacitors have long been formed using printing technology, such as screen printing. More recently, advanced printing techniques have been used to fabricate active devices, such as light emitting diodes and transistors. Printed electronics have historically been pursued utilizing various compositions of organic semiconducting materials, particularly solution-processable variants of conjugated hydrocarbons and aromatic hydrocarbons, such as polythiophenes and pentacene. The need for such materials has been based on the assumption that organic compositions are imperative for solution processability. While solution processes have been widely demonstrated for organic semiconductors, the performance of the semiconductive device, namely field effect mobility, has been shown to be several orders of magnitude lower than desired for applications requiring performance similar to that of amorphous silicon, particularly when moved to a graphic arts print press (where field effect mobility values less than 1 cm²/Vs are found). Although higher mobility values are possible with improved processing, organic semiconductors tend to be p-type, with n-type materials often of lower reliability and/or increased sensitivity to the environment. Inorganic semiconducting materials, including traditional silicon and germanium particles, semiconducting metal oxides (such as ZnO and SnO₂) and other semiconductive binary metal chalcogenides (such as CdSe) have high mobility compared to organic semiconducting materials, but are traditionally deposited using high-temperature film growth processes, by means of gas-phase decomposition of precursors in chemical vapor deposition. ZnO semiconductor layers have also been formed by conventional vacuum deposition methods such as ion-beam sputtering, rf sputtering, or pulsed laser deposition. Devices formed using these inorganic semiconducting materials also depend heavily on a select few substrate surfaces and dielectrics (such as very thin and smooth SiO₂), very thin semiconducting layers (30 nm or less), and/or high temperature annealing above 600° C. to improve crystallinity. These techniques are also not compatible with modern high speed printing techniques required to produce low cost products. It would be a significant addition to the art if a method to create printed semiconductive devices with inorganic semiconductors could be found that does not require high temperature treatments.

### BRIEF DESCRIPTION OF THE FIGURES

The accompanying figures, where like reference numerals refer to identical or functionally similar elements throughout the separate views and which together with the detailed description below are incorporated in and form part of the specification, serve to further illustrate various embodiments and to explain various principles and advantages all in accordance with the present invention.

FIG. 1 is a flow chart outlining a low temperature process for creating semiconductive devices by printing, in accordance with some embodiments of the invention.

FIG. 2 is a partial cross section of a printed nanoparticle semiconductive device, in accordance with some embodiments of the invention.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

### DETAILED DESCRIPTION

Before describing in detail embodiments that are in accordance with the present invention, it should be observed that the embodiments reside primarily in combinations of method and apparatus components related to semiconductor devices, and in particular, low cost semiconductor devices that contain nanoparticles of the semiconductive element. Accordingly, the apparatus components and methods have been represented where appropriate by conventional symbols in the drawings, showing only those specific details that are pertinent to understanding the embodiments of the present invention so as not to obscure the disclosure with details that will be readily apparent to those of ordinary skill in the art having the benefit of the description herein.

In this document, relational terms such as first and second, top and bottom, and the like may be used solely to distinguish one entity or action from another entity or action without necessarily requiring or implying any actual such relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “comprises . . . a” does not, without more constraints, preclude the existence of additional identical elements in the process, method, article, or apparatus that comprises the element. The term “nanoparticle” as used herein refers to a particle with at least one dimension less than 100 nm.

A low-temperature process for creating a semiconductive device by printing a liquid composition containing semiconducting nanoparticles will now be described. The semiconductive device is formed on a polymeric substrate by printing a composition that contains nanoparticles of inorganic semiconductor suspended in a carrier, using a graphic arts printing method. The printed deposit is then heated to remove substantially all of the carrier from the printed deposit. The low-temperature process does not heat the substrate or the printed deposit above 300° C. The mobility of the resulting semiconductive device is between about 10 cm²/Vs and 200 cm²/Vs. It is expected that one of ordinary skill, notwithstanding possibly significant effort and many design choices motivated by, for example, available time, current technology, and economic considerations, when guided by the concepts and principles disclosed herein will be readily capable of generating such semiconductive devices with minimal experimentation.

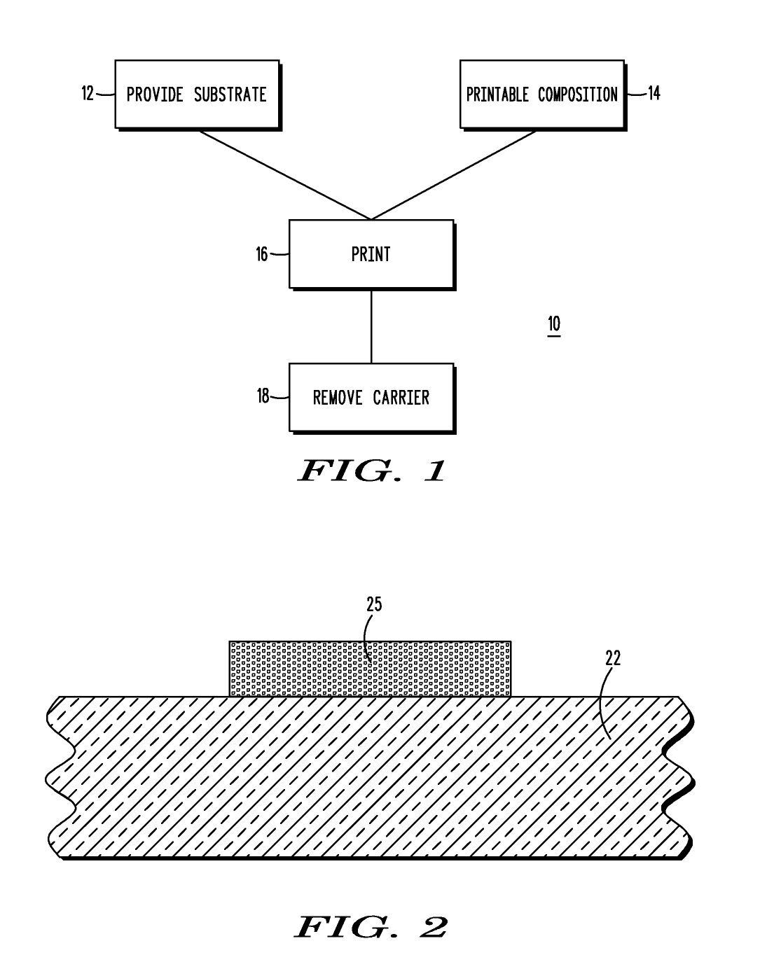

Referring now to FIG. 1, a process for forming a nanoparticle semiconductor device is generally depicted at reference numeral 10. A smooth polymeric film is used 12 as the substrate for the semiconductive device. A printable composition 14 contains nanoparticles of inorganic semiconductor suspended in a carrier. The printable composition is printed 16 on the substrate using a graphic arts method to form a printed deposit of the composition. The carrier is then removed 18 from the printed deposit, taking care to not heat the deposit above 300° C. or above the glass transition temperature of the substrate. Those skilled in the art of film technology will appreciate that removing a carrier does not always constitute removing every last molecule of material, but substantially removing enough so as to provide the desired end properties, such as, for example, creating an electrically stable film.

Referring now to FIGS. 1 & 2, the film used as the substrate 22 to be printed upon may be any of a number of commercially available polymers, such as polyamide, polyimide, polyetherimide, polysiloxane, polyurethane, polyamide-imide, polyester, polyacrylate, paper, or combinations thereof. These films are flexible, and provide some transmittance of visible light. The inorganic semiconductor is composed of one or more inorganic semiconducting materials selected from the Periodic Table of the Elements Group IV, binary Group III-V, binary Group II-VI, or combinations of these. By way of example, but not limitation, semiconductors such as ZnO, SnO₂, Si, Ge, GaAs, GaP, GaSb, GaN, InSb, InAs, InP, and combinations, compounds, or alloys thereof can be used. The semiconductor can be doped or undoped. Doping of the nanoparticles can be used to optimize device performance, however, it has been shown that undoped nanoparticle inks may be suitable for thin film transistor operation. The semiconductors are provided as nanoparticles, generally in particle sizes around 10-20 nanometers or even particle sizes up to 100 nanometers. Nanoparticles are well known to have a very high ratio of surface area to volume. The properties of these materials change as their size approaches the nanoscale and as the percentage of atoms at the surface of a material becomes significant. Each nanoparticle consists of a single crystal that is roughly spherical providing improved packing of particles after deposition. In one embodiment, the nanoparticle shape is selected such that the ratio of the largest dimension to the smallest dimension is between 1.0 and about 1.5. The particles have a maximum size of one-fifth of the smallest feature size to be printed. The nanoparticles of inorganic semiconductor are suspended in a carrier, such as a liquid solvent, at a concentration of less than 50% by weight. The carrier does not dissolve the nanoparticles, but suspends them in a dispersion. Suspensions of nanoparticles are possible because the interaction of the particle surface with a carrier solvent is strong enough to overcome differences in density, which result in a material either sinking or floating in a liquid. Some solvents that can be used are primary alkyl alcohols, alkyl diols, alkyl polyols, water, alkyl glycol ethers, and alkyl glycol acetates. Prevention of particle agglomeration for concentrations of greater than 10 wt % is accomplished using an appropriate chemical additive as is well known in the suspension chemistry art. The surface of the nanoparticle is not chemically modified with organic or inorganic compounds. The formulations show improvements of electrical conductivity of several orders of magnitude, improved adhesion to dielectric layers, and superior contact behavior. Although the carrier solvent is selected to provide sufficient (30% by weight) dispersion without significant use of other additives, surfactants may be employed to optimize the rheology and stability of the printable ink composition, and are carefully selected so as to not affect the device electrical performance. The inorganic semiconducting ink can be deposited by a variety of well known graphic arts processes employing contact and non-contact printing methods such as spin coating, roller coating, curtain coating, spraying, gravure printing, screen printing, inkjet printing, flexo printing, offset lithography printing, and microdispensing. These techniques are amenable to high speed printing, enabling low cost devices to be made, and are much less capital intensive than conventional vacuum deposition techniques. The printable nanoparticle semiconductor composition is printed on the substrate 22 to create a deposit 25 of the composition in a predetermined pattern. The printed deposit is then dried, for example by heating, to remove most or all of the carrier. Since the solvents enumerated above have a relatively low boiling point and are volatile below 150° C., the deposit does not need to be annealed at the high temperatures employed in the prior art. Depending on the solvent used, some very minor traces of the various carrier solvents might remain entrapped in the printed semiconductor deposit, in which case, we find that temperatures approaching 300° C. might briefly be needed to remove the last traces of carrier. Any additives that may have been included in the formulation are concurrently removed during this treatment to enhance device mobility. Our low temperature process allows the use of polymers as a substrate, which would be destroyed at the high temperatures (in excess of 600° C.) used in the prior art. The device mobility of devices 20 formed in accordance with our invention is about 10 to 200 cm²/Vs. In comparison, mobility of conventional inorganic semiconductors formed on silicon is about 500-1000 cm²/Vs, and prior art printed organic semiconductor devices are below 0.1 cm²/Vs, and often less than 0.001 cm²/Vs.

The inorganic semiconducting devices and process described in this invention allow for improved electrical performance for non-polymeric semiconductor inks. These modifications allow for improved on/off ratio and improved current carrying capability for device structures using relatively thick printed dielectrics. The modifications also allow for environmental immunity for air or moisture sensitive semiconducting particles. These non-polymeric particle inks enable very high mobility devices, such as field effect transistors, to be fabricated using conventional printing processes.

In the foregoing specification, specific embodiments of the present invention have been described. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of present invention. The benefits, advantages, solutions to problems, and any element(s) that may cause any benefit, advantage, or solution to occur or become more pronounced are not to be construed as a critical, required, or essential features or elements of any or all the claims. The invention is defined solely by the appended claims including any amendments made during the pendency of this application and all equivalents of those claims as issued.

What is claimed is:

1. A low-temperature process for creating a semiconductive device by printing a liquid composition containing semiconducting nanoparticles, comprising:
providing a polymeric substrate;
providing a printable composition comprising nanoparticles of inorganic semiconductor suspended in a carrier;
printing the printable composition on the polymeric substrate using a graphic arts printing method, so as to form a printed deposit of the composition;
substantially removing the carrier from the printed deposit; and
wherein the low-temperature process does not comprise heating the printed deposit above 300° C.

2. The process as described in claim 1, wherein substantially removing the carrier comprises heating the printed deposit at a temperature less than or equal to 150° C.

3. The process as described in claim 1, wherein the nanoparticles of inorganic semiconductor comprise particle sizes less than 100 nanometers.

4. The process as described in claim 3, wherein the nanoparticles of inorganic semiconductor comprise particle sizes substantially 20 nanometers.

5. The process as described in claim 1, wherein providing a printable composition comprises providing nanoparticles of one or more inorganic semiconducting materials selected from the group consisting of elements from the Periodic Table of the Elements Group IV, binary Group III-V, binary Group II-VI, or combinations thereof.

6. The process as described in claim 1, wherein providing a printable composition comprises providing nanoparticles of inorganic semiconductor suspended in one or more carriers selected from the group consisting of primary alkyl alcohols, alkyl diols, alkyl polyols, water, alkyl glycol ethers, and alkyl glycol acetates.

7. The process as described in claim 1, wherein a graphic arts printing method comprises one or more methods selected from the group consisting of spin coating, roller coating, curtain coating, spraying, gravure printing, screen printing, inkjet printing, flexo printing, offset lithography printing, and microdispensing.

8. The process as described in claim 1, wherein the ratio of the largest dimension to the smallest dimension of the nanoparticles is between 1.0 and about 1.5.

9. The process as described in claim 1, wherein printing the printable composition comprises printing a predetermined pattern.

10. The process as described in claim 1, wherein the surface of the nanoparticles is not modified with organic or inorganic compounds.

11. The process as described in claim 1, wherein the mobility of the semiconductive device is between about 10 cm²/Vs and 200 cm²/Vs.

12. A low-temperature process for creating a semiconductive device by printing a liquid composition containing semiconducting nanoparticles, comprising:
providing an electrically insulating substrate;
providing a printable composition comprising nanoparticles less than 100 nanometers of one or more inorganic semiconductors selected from the group consisting of elements from the Periodic Table of the Elements Group IV, binary Group III-V, binary Group II-VI, and combinations, compounds, or alloys thereof suspended in a carrier comprising one or more solvents selected from the group consisting of primary alkyl alcohols, alkyl diols, alkyl polyols, water, alkyl glycol ethers, and alkyl glycol acetates;
printing the printable composition on the insulating substrate using a graphic arts printing technique, so as to form a printed deposit of the composition in a predetermined pattern; and
substantially removing the carrier from the printed deposit by heating the printed deposit at a temperature not to exceed 150° C.

13. The process as described in claim 12, wherein the nanoparticles of inorganic semiconductor comprise particle sizes substantially 20 nanometers.

14. The process as described in claim 12, wherein a graphic arts printing technique comprises one or more techniques selected from the group consisting of spin coating, roller coating, curtain coating, spraying, gravure printing, screen printing, inkjet printing, flexo printing, offset lithography printing, and microdispensing.

15. The process as described in claim 12, wherein the ratio of the largest dimension to the smallest dimension of the nanoparticles is between 1.0 and about 1.5.

16. An inorganic semiconductive device formed on a polymeric substrate, comprising a substrate having nanoparticles of inorganic semiconductor printed in a predetermined pattern using a graphic arts printing technique, wherein the mobility of the inorganic semiconductive device is between about 10 cm²/Vs and 200 cm²/Vs.

17. The inorganic semiconductive device as described in claim 16, wherein nanoparticles of inorganic semiconductor comprises one or more inorganic semiconducting materials selected from the group consisting of elements from the Periodic Table of the Elements Group IV, binary Group III-V, binary Group II-VI, or combinations thereof.

18. The inorganic semiconductive device as described in claim 16, wherein the nanoparticles of inorganic semiconductor range between about 20 and about 100 nanometers in diameter.

19. The inorganic semiconductive device as described in claim 16, wherein the substrate comprises a polymeric or paper substrate.

20. The inorganic semiconductive device as described in claim 16, wherein the inorganic semiconductive device is a field-effect transistor.
